(19) United States
(12) Patent Application Publication
(10) Pub. No.: US 2014/0063941 A1
(43) Pub. Date: Mar. 6, 2014

(54) SEMICONDUCTOR MEMORY DEVICE

(71) Applicant: KABUSHIKI KAISHA TOSHIBA, Tokyo (JP)

(72) Inventor: Tokumasa HARA, Kawasaki-shi (JP)

(73) Assignee: Kabushiki Kaisha Toshiba, Tokyo (JP)

(21) Appl. No.: 13/832,498

(22) Filed: Mar. 15, 2013

Related U.S. Application Data
(60) Provisional application No. 61/695,813, filed on Aug. 31, 2012.

(51) Int. Cl. G11C 16/04

(52) U.S. Cl. CPC G11C 16/04
USPC 365/185.03

(57) ABSTRACT

According to one embodiment, a semiconductor memory device includes memory cells and memory strings. When lower-page data is first written into a memory string, all memory cells corresponding to the lower-page data are made write-target, a program-verifying level of first ones of the write-targeted memory cells is a first threshold level, and a program-verifying level of second ones of the write-targeted memory cells is a second threshold level. The first threshold level corresponds to data associated with the lowest threshold level and is higher than a third threshold level. The second threshold level is higher than the first threshold level.

### CROSS-REFERENCE TO RELATED APPLICATIONS

This application claims the benefit of U.S. Provisional Application No. 61/695,813, filed Aug. 31, 2012, the entire contents of which are incorporated herein by reference.

### FIELD

Embodiments described herein relate generally to a semiconductor memory device.

### BACKGROUND

In recent years, a NAND flash memory with three-dimensionally arranged memory cells has been known.

### BRIEF DESCRIPTION OF THE DRAWINGS

FIG. 1 is a block diagram of a semiconductor memory device according to a first embodiment;

FIG. 2 is a circuit diagram of a memory cell array according to the first embodiment;

FIG. 3 and FIG. 4 are perspective view and sectional view of the memory cell array according to the first embodiment, respectively;

FIG. 5 is a diagram showing a threshold distribution of a memory cell according to the first embodiment;

FIG. 6 is a graph showing a threshold distribution of a memory cell according to the first embodiment;

FIG. 7 is a flowchart to explain a data erasing method according to the first embodiment;

FIG. 8 is a flowchart to explain a data writing method according to the first embodiment;

FIG. 9 is a timing chart to explain a data writing method according to the first embodiment;

FIG. 10 is a table to explain a data writing method according to the first embodiment;

FIG. 11 to FIG. 14 are schematic views of a memory cell array and sense amplifiers according to the first embodiment;

FIG. 15 is a schematic view of a memory cell array and a threshold distribution;

FIG. 16 is a schematic view of a memory cell array;

FIG. 17 is a flowchart to explain a data writing method according to a second embodiment;

FIG. 18 is a timing chart to explain the data writing method according to the second embodiment;

FIG. 19 is a diagram to explain the data writing method according to the second embodiment; and

FIG. 20 to FIG. 23 are schematic views of memory cell arrays and sense amplifiers according to the second embodiment.

### DETAILED DESCRIPTION

In general, according to one embodiment, a semiconductor memory device includes: a plurality of memory cells each of which is capable of holding two or more bits of data according to a threshold level; and a plurality of memory strings each of which includes a plurality of memory cells connected in series. Data is written in units of page into memory cells and the page includes a lower page and upper page which are associated with lower bits and upper bits of the two or more bits of data, respectively. When lower-page data is first written into a memory string, all memory cells corresponding to the lower-page data are made write-target, a program-verifying level of first ones of the write-targeted memory cells is a first threshold level, and a program-verifying level of second ones of the write-targeted memory cells is a second threshold level. The first threshold level corresponds to data associated with the lowest threshold level of the two or more bits of data and is higher than a third threshold level. The third level is a threshold level at which data has been erased. The second threshold level is higher than the first threshold level.

### 1. First Embodiment

A semiconductor memory device according to a first embodiment will be explained. Hereinafter, a semiconductor memory device will be explained, taking, as an example, a three-dimensional stacked NAND flash memory with memory cells stacked above a semiconductor substrate.

1.1 Configuration of Semiconductor Memory Device

First, the configuration of a semiconductor memory device according to the first embodiment will be explained.

1.1.1 Overall Configuration of Semiconductor Memory Device

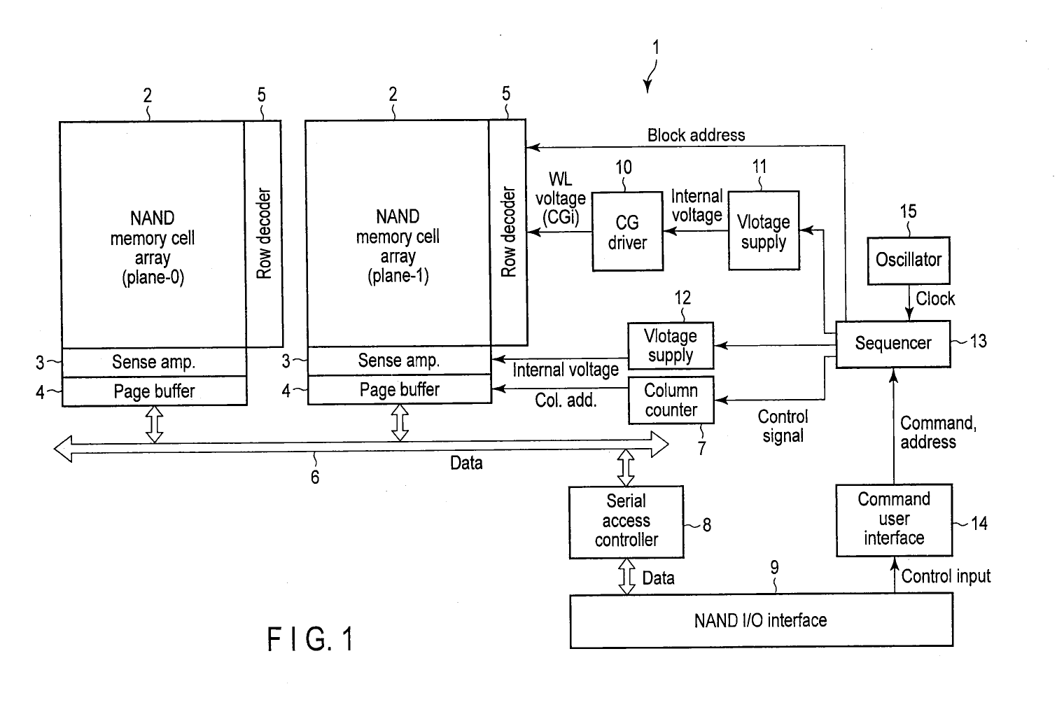

FIG. 1 is a block diagram of a NAND flash memory according to the first embodiment. As shown in FIG. 1, the NAND flash memory 1 includes memory cell arrays 2, sense amplifiers 3, page buffers 4, row decoders 5, a data bus 6, a column counter 7, a serial access controller 8, an I/O interface 9, a CG driver 10, voltage generator circuits 11, 12, a sequencer 13, a command user interface 14, and an oscillator 15.

Each of the memory cell arrays 2 includes a plurality of nonvolatile memory cells three-dimensionally stacked. In the memory cell array 2, memory cells in the same row are connected to the same word line and memory cells in the same column are connected to the same bit line. Write data to memory cells and read data from memory cells are transferred via bit lines. Although the example of FIG. 1 shows a case where the memory 1 includes two memory cell arrays, the memory may include one memory cell array or three or more memory cell arrays.

Each memory cell array 2 is provided with a sense amplifier 3, a page buffer 4, and a row decoder 5. The sense amplifier 3 senses and amplifies data read from a memory cell onto a bit line. The page buffer 4 includes a plurality of latch circuits associated with respective bit lines. When data is read, the page buffer 4 temporarily holds data sensed and amplified by the sense amplifier 3 and outputs the amplified data to the data bus 6. In addition, when data is written, the page buffer 4 temporarily holds write data and then transfers the data to a bit line. The row decoder 5 selects a row direction of the memory cell array 2. That is, the row decoder 5 selects a word line.

The voltage generator circuit 12 generates a voltage to be applied to a bit line in reading data or writing data and supplies the voltage to the sense amplifier 3. The sense amplifier 3 applies a necessary voltage to a bit line according to write data in the page buffer 4. The column counter 7 receives a control signal from the sequencer 13 in reading data or writing data. Then, the column counter 7 obtains a column address from the received control signal and outputs the column address to the page buffer 4. The page buffer 4 decodes the column address and connects a latch in the page buffer 4 to the data bus 6 on the basis of the decoding result.

The voltage generator circuit 11 generates a voltage to be applied to a word line in reading, writing, or erasing data and supplies the voltage to the CG driver 10. The CG driver 10 transfers the necessary voltages supplied from the voltage generator circuit 11 to a word line selected by the row decoder 5 and the unselected word lines.

The I/O interface 9 supervises the exchange of signals with a controller (not shown) or a host device that control the NAND flash memory 1. When data is written, the I/O interface 9 receives a control signal (a write command and an address) and write data from the controller. Then, the I/O interface 9 transfers the control signal to the command user interface 14 and the write data to the serial access controller 8. When data is read, the I/O interface 9 receives a control signal (a read command and an address) from the controller and transfers these to the command user interface 14. Then, the I/O interface 9 receives read data from the serial access controller 8 and transfers the data to the controller.

When data is read, the data bus 6 transfers read data from the page buffer 4 to the serial access controller 8. When data is written, the data bus 6 transfers write data from the serial access controller 11 to the page buffer 4.

The serial access controller 11 controls parallel transfer of data on the data bus 6. When data is written, the data from the controller is transmitted to the I/O interface 9 serially. The serial data is transferred parallely over the data bus 6 to the page buffer 4. When data is read, the process is performed in the reverse order. Such control is performed by the serial access controller 11.

The command user interface 14 receives a control signal from the I/O interface 9 and decodes the control signal, obtaining a command and an address. Then, the command user interface 14 transfers these to the sequencer 13. The oscillator 15 generates a clock.

The sequencer 13 controls the operation of the entire NAND flash memory 1. The sequencer 13 controls the operation of the column counter 7 and voltage generator circuits 12, 13 on the basis of the clock from the oscillator 15 and the command and address from the command user interface 14.

1.1.2 Memory Cell Array

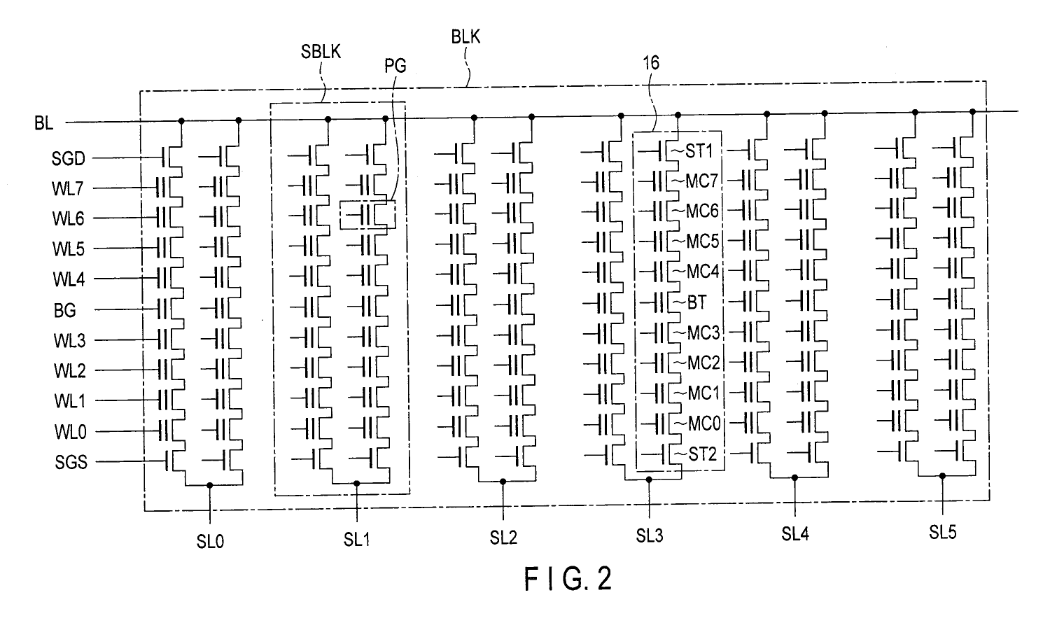

Next, the configuration of the memory cell array 2 will be explained in detail. FIG. 2 is a circuit diagram of a part of the memory cell array 2.

FIG. 2 shows only a configuration related to a certain bit line BL. Actually, the memory cell array 2 includes a plurality of bit liens BL. Therefore, the memory cell array 2 includes a plurality of units of the configuration shown in FIG. 2. A set of the configurations of FIG. 2 forms a block BLK. A block BLK is, for example, a data erasing unit. Data in the same block is erased en bloc.

As shown in FIG. 2, a block BLK includes a plurality of NAND strings 16. A NAND string 16 includes, for example, eight memory cell transistors (sometimes simply referred to as memory cells) MC0 to MC7, select transistors ST1, ST2, and a back-gate transistor BT.

Each of the memory cell transistors MC, which has a stacked gate that includes a control gate and a charge storage layer, holds data in a nonvolatile manner. The number of memory cell transistors MC in the NAND string 16 is not limited to eight and may be 16, 32, 64, 128, or the like. That is, the number of memory cell transistors is not restrictive. Like the memory cell transistor MC, the back-gate transistor BT has a stacked gate that includes a control gate and a charge storage layer. Here, the back-gate transistor BT is not for holding data and functions as just a current path in writing or reading data.

The memory cell transistors MC and back-gate transistor BT are arranged so that their current paths may be connected in series between select transistors ST1, ST2. The back-gate transistor BT is provided between memory cell transistors MC3 and MC4. The current path of the memory cell transistor MC7 at one end of the series connection is connected to one end (source) of the current path of select transistor ST1. The current path of memory cell transistor MC0 at the other end is connected to one end (drain) of the current path of select transistor ST2.

A plurality of units of the NAND string 16 with the above configuration are connected to each bit line BL. That is, the drain of select transistor ST1 is connected to the corresponding bit line BL. Moreover, in the first embodiment, two NAND strings 16 connected to the same bit line BL are connected to the same source line SL (any one of SL0 to SL5). That is, the source of select transistor ST2 is connected to the corresponding source line SL. As for each bit line BL, a set of two NAND strings 16 connected to the same source line SL forms a sub-block SBLK. Data may be erased in units of the sub-block SBLK.

The gate of select transistor ST1 is connected to the corresponding select gate line SGD and the gate of select transistor ST2 is connected to the corresponding select gate line SGS. In addition, the control gates of memory cell transistors MC0 to MC7 are connected to word lines WL0 to WL7, respectively. The control gate of a back gate transistor BT is connected to a back gate line BG.

These interconnection lines SGD, SGS, WL, BG are shared by a plurality of NAND strings 16 connected to different bit lines BL. Although a plurality of NAND strings 16 connected to the same bit line BL may share each of word lines WL0 to WL7, the select gate lines SGD, SGS are independent. Therefore, by controlling the select gate lines SGD, SGS suitably, any one of the NAND strings 16 connected to the same bit lines BL can be selected.

Furthermore, in the NAND strings 16 connected to the same select gate lines SGD, SGS, a set of memory cells MC connected to the same word line WL forms a unit called a page PG. Data is written or read in pages.

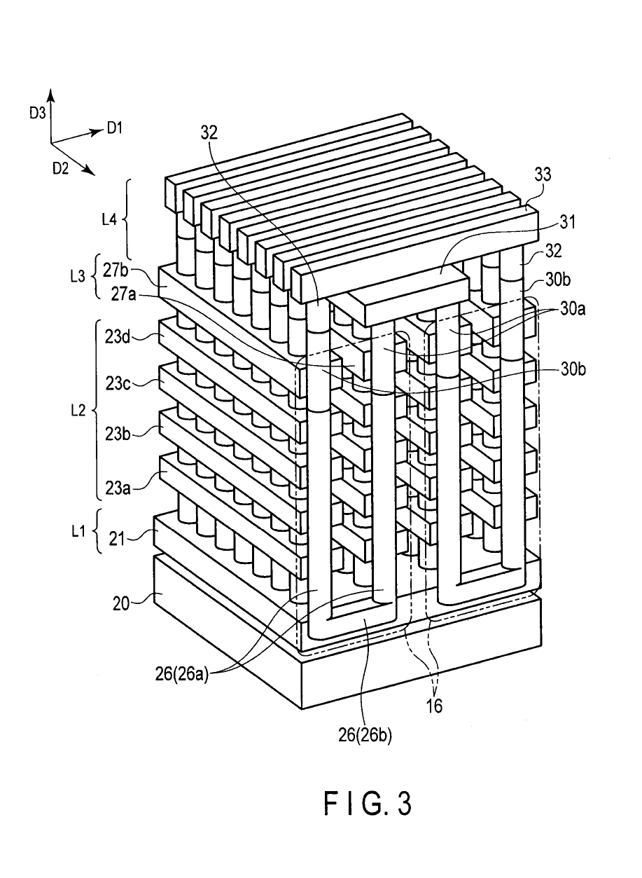

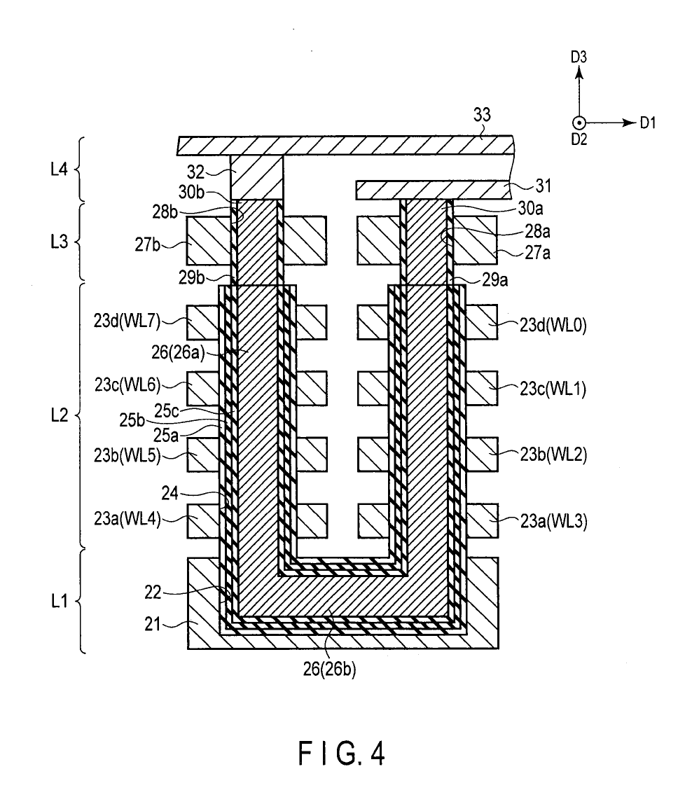

Next, a three-dimensional stacked structure of the memory cell array 2 will be explained with reference to FIGS. 3 and 4. FIGS. 3 and 4 are a perspective view and a sectional view of the memory cell array 2.

As shown in FIG. 3, the memory cell array 2 is provided above a semiconductor substrate 20. The memory cell array 2 includes a back gate transistor layer L1, a memory cell transistor layer L2, a select transistor layer L3, and an interconnection layer L4 formed in that order above the semiconductor substrate 20.

The back gate transistor layer L1 functions as a back gate transistor BT. The memory cell transistor layer L2 functions as memory cell transistors MC0 to MC7 (NAND string 16). The select transistor layer L3 functions as select transistor ST1, ST2. The interconnection layer L4 functions as source lines SL and bit lines BL.

The back gate transistor layer L1 includes a back gate conducting layer 21. The back gate conducting layer 21 is formed so as to expand two-dimensionally in a first direction and a second direction parallel with the semiconductor substrate 20 (that is, the first and second directions are perpendicular to a third direction in which memory cells are stacked). The back gate conducting layer 21 is segmented in memory blocks BLK. The back gate conducting layer 21 is made of, for example, polysilicon. The back gate conducting layer 21 functions as back gate lines BG.

In addition, the back gate conducting layer 21 has a back gate hole 22 in it as shown in FIG. 4. The back gate hole 22 is made so as to recess the back gate conducting layer 21. The back gate hole 22 is formed into almost a rectangular shape whose longitudinal direction is in a first direction when viewed from above.

The memory cell transistor layer L2 is formed on the back gate conducting layer L1. The memory cell transistor layer L2 includes word line conducting layers 23a to 23d. The word line conducting layers 23a to 23d are stacked one on top of another, with an interlayer insulating layer (not shown) interposed therebetween. The word line conducting layers 23a to 23d are formed into stripes extending in a second direction with a specific pitch in the first direction. The word line conducting layers 23a to 23d are made of, for example, polysilicon. The word line conducting layer 23a functions as control gates (word lines WL3, WL4) of memory cell transistors MC3, MC4. The word line conducting layer 23b functions as control gates (word lines WL2, WL5) of memory cell transistors MC2, MC5. The word line conducting layer 23c functions as control gates (word lines WL1, WL6) of memory cell transistors MC1, MC6. The word line conducting layer 23d functions as control gates (word lines WL0, WL7) of memory cell transistors MC0, MC7.

The memory cell transistor layer L2 has a memory hole 24 in it as shown in FIG. 4. The memory hole 24 is made to extend through the word line conducting layers 23a to 23d. The memory hole 24 is made so as to align with the proximity of the end of the back gate hole 22 in the first direction.

In addition, the back gate transistor layer L1 and memory cell transistor layer L2 include a block insulating layer 25a, a charge accumulation layer 25b, a tunnel insulating layer 25c, and a semiconductor layer 26 as shown in FIG. 4. The semiconductor layer 26 functions as a body (or a back gate of each transistor) of the NAND string 16.

The block insulating layer 25a is formed to a specific thickness on the sidewalls facing the back gate hole 22 and memory hole 25 as shown in FIG. 4. The charge accumulation layer 25b is formed to a specific thickness on the sidewall of the block insulating layer 25a. The tunnel insulating layer 25c is formed to a specific thickness on the sidewall of the charge accumulation layer 25b. The semiconductor layer 26 is formed so as to contact the sidewall of the tunnel insulating layer 25c. The semiconductor layer 26 is formed so as to fill the back gate hole 22 and memory hole 24.

The semiconductor layer 26 is formed into a U-shape when viewed from the second direction. Specifically, the semiconductor layer 26 includes a pair of columnar parts 26a extending perpendicularly to the surface of the semiconductor substrate 20 and a connecting part 26b that connects the lower ends of the pair of columnar parts 26a.

The block insulating layer 25a and tunnel insulating layer 25c are made of, for example, silicon oxide (SiO₂). The charge accumulation layer 25b is made of, for example, silicon nitride (SiN). The semiconductor layer 26 is made of polysilicon. The block insulating layer 25a, charge accumulation layer 25b, tunnel insulating layer 25c, and semiconductor layer 26 form a MONOS transistor functioning as a memory cell transistor MC.

In other words, the back-gate transistor layer L1 is so configured that the tunnel insulating layer 25c is formed so as to surround the connecting part 26b and that the back-gate conducting layer 21 is formed so as to surround the connecting part 26b.

Furthermore, the memory cell transistor layer L2 is so configured that the tunnel insulating layer 25c is formed so as to surround the columnar part 26a, the charge accumulation layer 25b is formed so as to surround the tunnel insulating layer 25c, the block insulating layer 25a is formed so as to surround the charge accumulation layer 25b, and the word line conducting layers 23a to 23d are formed so as to surround the block insulating layers 25a to 25c and the columnar part 26a.

The select transistor layer L3 includes conducting layers 27a and 27b as shown in FIGS. 3 and 4. The conducting layers 27a and 27b are formed into stripes that extend in the second direction so as to have a specific pitch in the first direction. A pair of conducting layers 27a and a pair of conducting layers 27b are arranged alternately in the first direction. The conducting layers 27a are formed on one columnar part 26a and the conducting layers 27b are formed on the other columnar part 26a.

The conducting layers 27a and 27b are made of polysilicon. The conducting layer 27a functions as the gate (select gate line SGS) of select transistor ST2 and the conducting layer 27b functions as the gate (select gate line SGD) of select transistor ST1.

The select transistor layer L3 has holes 28a and 28b in it as shown in FIG. 4. The holes 28a and 28b extend through the conducting layers 27a and 27b, respectively. Each of the holes 28a and 28b aligns with the memory holes 24.

The select transistor layer L3 includes gate insulating layers 29a and 29b and semiconductor layers 30a and 30b as shown in FIG. 4. The gate insulating layers 29a and 29b are formed on the sidewalls facing the holes 28a and 28b, respectively. The semiconductor layers 30a and 30b are each formed into a columnar shape extending perpendicularly to the surface of the semiconductor substrate 20 so as to contact the gate insulating layers 29a and 29b, respectively.

The gate insulating layers 29a and 29b are made of, for example, silicon oxide (SiO₂). The semiconductor layers 30a and 30b are made of, for example, polysilicon.

In other words, the select transistor layer L3 is so configured that the gate insulating layer 29a is formed so as to surround the columnar semiconductor layer 30a, the conducting layer 27a is formed so as to surround the gate insulating layer 29a and the semiconductor layer 30a, the gate insulating layer 29b is formed so as to surround the columnar semiconductor layer 30b, and the conducting layer 27b is formed so as to surround the gate insulating layer 29b and the semiconductor layer 30b.

The interconnection layer L4 is formed on the select transistor layer L3 as shown in FIGS. 3 and 4. The interconnection layer L4 includes a source line layer 31, a plug layer 32, and a bit line layer 33. The source line layer 31 is formed into a plate extending in the second direction. The source line layer 31 is formed so as to contact the upper surfaces of a pair of semiconductor layers 27a adjacent to each other in the first direction. The plug layer 32 is formed so as to contact the upper surface of the semiconductor layer 27b and extend perpendicularly to the surface of the semiconductor substrate 20. The bit line layer 33 is formed into stripes that extend in the first direction with a specific pitch in the second direction. The bit line layer 33 is formed so as to contact the upper surfaces of the plug layers 32. The source line layer 31, plug layer 32, and bit line layer 33 are made of such a metal as tungsten (W). The source line layer 31 functions as source lines SL and the bit line layer 33 functions as bit lines BL as explained in FIGS. 1 and 2.

1.1.3 Threshold Distribution in a Memory Cell

Next, a threshold distribution in a memory cell MC according to the first embodiment will be explained with reference to FIG. 5.

As shown in FIG. 5, each memory cell MC can hold, for example, 2-bit data according to its threshold level. The 2-bit data includes, for example, “11,” “01,” “00,” “10” in ascending order of threshold level.

The threshold level of a memory cell that holds “11” data is at “Er” level or “EP” level. Er level is a threshold level in a state where data has been erased by drawing charges from the charge accumulation layer. Er level may be a negative value. EP level is a threshold level in a state where charges have been injected into the charge accumulation layer. EP level is equal to or higher than Er level and has a positive value.

Each of “01,” “00,” and “10” is a threshold level in a state where charges have been injected into the charge accumulation layer. The threshold level of a memory cell that holds “01” data is at “A” level and is higher than each of Er level and EP level. The threshold level of a memory cell that holds “00” data is at “B” level and is higher than A level. The threshold level of a memory cell that holds “10” data is at “C” level and is higher than B level.

Data is written bit by bit in 2-bit data in such a manner that the lower bit data is written first and then the upper bit data is written. As described above, data is written in pages. Therefore, when a word line has been selected, the lower bit data is written en bloc to a plurality of memory cells connected to the selected word line and then the upper bit data is written en bloc to the memory cells. That is, when a memory cell MC holds 2-bit data, two pages associated with the upper bit data and lower bit data are allocated to one word line WL. Hereinafter, these are called the upper page and lower page.

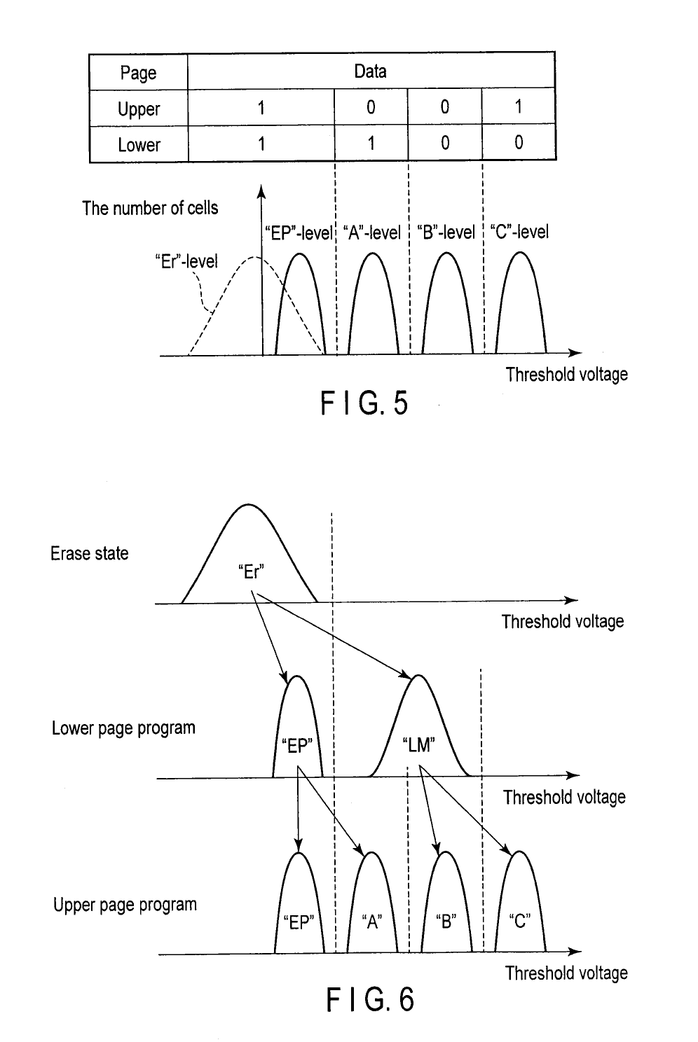

FIG. 6 is a graph showing changes in a threshold distribution in writing data. As shown in FIG. 6, when the lower page data has been written to a memory cell MC in an erased state, the threshold level transits to EP level or an “LM” level according to the data. The LM level is higher than EP level and lower than C level. More specifically, when the lower page data is “1,” it is determined to be EP level. When the lower page data is “0,” it is determined to be LM level.

Next, when the upper page data has been written, the threshold level remains at EP level or transits to any one of A to C levels. More specifically, the threshold level of a memory cell MC in which 11 data has been written maintains EP level. The threshold level of a memory cell in which 01 data has been written transits from EP level to A level. The threshold level of a memory cell MC in which 00 data has been written transits from LM level to B level. The threshold level of a memory cell MC in which 10 data has been written transits from LM level to C level.

The operation of writing page data to cause the threshold level to transit to a desired level roughly includes the following two processes:

(1) the process of injecting charges into the charge accumulation layer to raise the threshold level, and

(2) the process of verifying whether the threshold level has reached the desired level as a result of item (1).

Hereinafter, the operation in item (1) is called “program” and the operation in item (2) is called “verification.” The operations in items (1) and (2) are carried out repeatedly. When the result of verification has shown that the threshold level has reached the desired level, the write operation is completed.

1.2 Operation of Semiconductor Memory Device

Next, the operation of the semiconductor memory device with the above configuration will be explained. Operations explained below are performed under the control of, for example, the sequencer 13 in response to an instruction from the controller.

1.2.1 Erase Operation

First, a data erase operation will be explained.

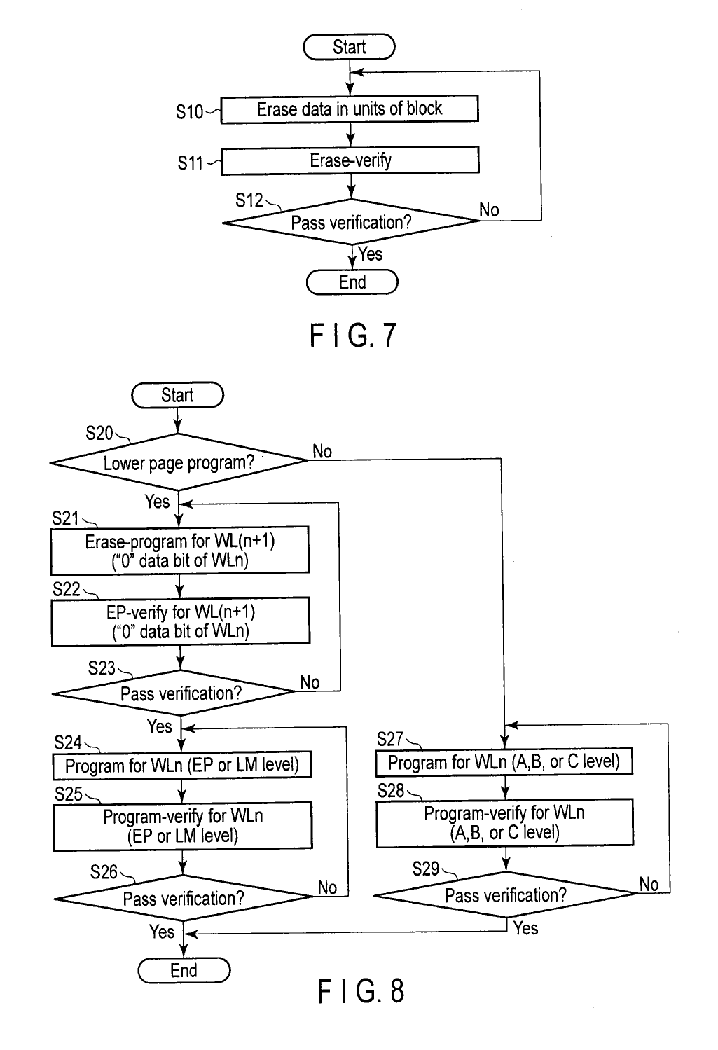

FIG. 7 is a flowchart to explain processing flow in erasing data.

As shown in FIG. 7, first, data is erased in blocks (step S10). As described above, data may be erased in sub-blocks SBLK. Data is erased by, for example, applying high voltages to bit lines BL and source lines SL to cause gate induced drain leakage (GIDL). A hole generated by GIDL causes the potential of the pillar 26 to rise. Then, applying a low voltage to word lines WL causes charges in the charge accumulation layer to be drawn into the pillar 26, thereby erasing data.

Next, erase-verification is performed (step S11). The erase-verification is the process of verifying, by reading data from the memory cell MC, whether the threshold level of a memory cell MC has dropped to a desired level (Er level) as a result of step S10. Hereinafter, if the result of verification has shown that the threshold level has reached the desired level, this is represented as “passing verification.” If the result has shown that the threshold level has not reached the desired level, this is represented as “missing verification.”

If all the memory cells MC have passed the erase-verification (Yes in step S12), the process is terminated. If any one of the memory cells MC has missed verification (No in step S12), the processes are repeated from step S10 for the memory cell MC.

As described above, as a result of erasing, the threshold levels of all the memory cells MC are at Er level.

1.2.2 Write Operation

Next, a data write operation will be explained.

FIG. 8 is a flowchart to explain processing flow in writing data. Like an erase operation, a write operation is performed under the control of, for example, the sequencer 13 in response to an instruction from the controller.

First, the sequencer 13 receives a write instruction and data for word line WLn (n being a natural number and ranging from 0 to 6 in the case of the configuration of FIG. 2) from the controller.

Then, the sequencer 13 determines whether the received data is lower-page data. If the received data is lower page data (Yes in step S20), first, an erase-program is executed for word line WL(n+1) (step S21). The erase-program is a program operation for raising the threshold level of Er level to EP level. A target for which the erase-program is executed in this step is a memory cell MC adjacent to word line WLn on the drain side and corresponding to a column whose received lower page data is “0.”

After step S21, an erase-program-verification is performed on the memory cell MC for which the erase-program has been executed (step S22). The erase-program-verification is the process of verifying whether the threshold level of the memory cell MC has reached EP level. If any one of the memory cells MC has missed the erase-program-verification (No in step S23), the erase-program is repeated for the verify-missed memory cell MC (step S21). At this time, the erase-program is not executed on the memory cells MC that have passed the verification.

If all the memory cells MC for which the erase-program has been executed have passed verification (Yes in step S23), the sequencer 13 programs lower page data (step S24) for a word line Wn (a word line WLn corresponding to an address received from the controller) specified by the controller and continues performing the program-verification (step S25). Steps S24 and S25 cause the threshold levels of all the memory cells MC connected to the word line WLn in the selected string to rise from Er level to EP level or LM level (Yes in step S26).

In step s20, if the received data is upper page data (No in step S20), the sequencer 13 programs upper page data for word line WLn (step S27) and continues performing the program-verification (step S28). Steps S27 and S28 cause any one of the memory cells MC connected to word line WLn in the selected string to rise to any one of A level to C level (Yes in step S29).

Data programming, including an erase-program, is performed as follows. The row decoder 5 selects a block BLK including a page specified by the controller. Then, the word lines WL in the selected block are connected to the CG driver 10. The CG driver 10 applies a high voltage VPGM to a word line to be programmed and an intermediate voltage VPASS (<VPGM) to the unselected word lines. VPASS is a voltage that turns on a memory cell MC, regardless of held data. VPGM is a high voltage for injecting charges into the charge storage layer. In addition, the CG driver 10 applies voltage Vsg to the select gate line SGD of a NAND string 16 to which a word line to be programmed belongs. Vsg is a voltage that turns on select transistor ST1. Moreover, the CG driver 10 applies 0 V to the other select gate lines SGD and SGS, thereby turning off these transistors. Furthermore, the page buffer 4 applies, to a bit line BL, a voltage corresponding to data received from the controller.

As a result, a voltage corresponding to the received data is transferred to the channel of the selected memory cell, with the result that charges are injected into the charge accumulation layer. In a NAND string 16 that does not include the selected memory cell, select transistor ST1 is made off, preventing data from being written.

1.2.3 Detailed Sequence of Writing

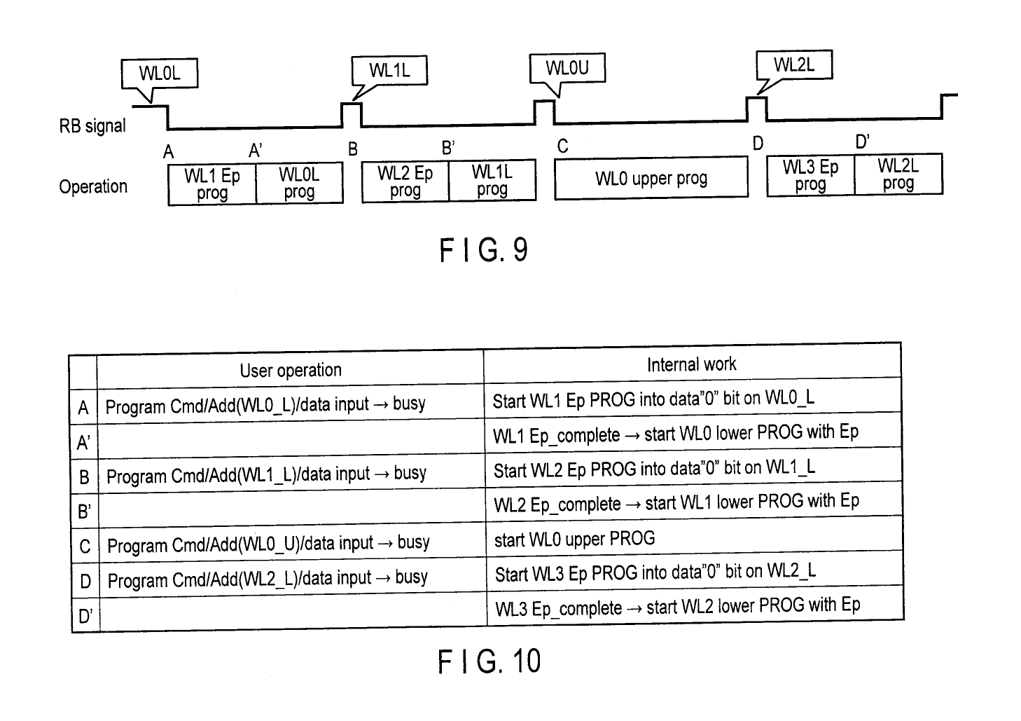

A detailed sequence of the write operation will be explained with reference to FIGS. 9 and 10. FIG. 9 is a timing chart to explain a ready/busy signal (RB signal) supplied from the NAND flash memory 1 to the controller and an operation flow. FIG. 10 is a table to explain the details of the operation shown in FIG. 9.

The RB signal is a signal that indicates whether the NAND flash memory 1 can accept an instruction. In the example of FIG. 9, a period when the RB signal is at a high (“H”) level corresponds to the ready state of the NAND flash memory 1. In the ready state, the NAND flash memory 1 can accept a write instruction, a read instruction, or an erase instruction from the controller. In contrast, a period when the RB signal is at a low (“L”) level corresponds to the busy state of the NAND flash memory 1. In the busy state, the NAND flash memory 1 accepts none of a write instruction, a read instruction, and an erase instruction. The RB signal is output from, for example, the I/O interface 9.

As shown in FIGS. 9 and 10, first, in a period when the RB signal is at “H” level, the controller instructs the NAND flash memory 1 to program a lower page for word line WL0. Specifically, as shown at point A in FIGS. 9 and 10, the controller inputs a program command, an address (corresponding to the lower page of WL0), and lower page data to the NAND flash memory 1. When a program command has been established at the command user interface 14 in response to this, the NAND flash memory 1 goes into the busy state.

When a program command has been established, an erase-program for word line WL1 is executed under the control of the sequencer 13 (steps S21 to S23 in FIG. 8) in the NAND flash memory 1. When the erase-program is completed, a lower-page program for word line WL0 is then executed as shown at point A′ in FIGS. 9 and 10 (steps S24 to S26 in FIG. 8). At this time, for a memory cell MC whose lower page data is “1,” a program (i.e., an erase-program) for raising the threshold level from Er level to EP level is executed.

When the lower page program for word line WL0 is completed, the NAND flash memory 1 goes into the ready state and the RP signal goes into the “H” level. Then, the controller instructs the NAND flash memory 1 to program lower page data for word line WL1. Specifically, as shown at point B in FIGS. 9 and 10, the controller inputs a program command, an address (corresponding to the lower page of WL1), and lower page data to the NAND flash memory 1. When a program command has been established at the command user interface 14 in response to this, the NAND flash memory 1 goes into the busy state.

When a program command has been established, an erase-program for word line WL2 is executed under the control of the sequencer 13 (steps S21 to S23 in FIG. 8). When the erase-program is completed, a lower-page program for word line WL1 is then executed as shown at point B′ in FIGS. 9 and 10 (steps S24 to S26 in FIG. 8). At this time, too, for a memory cell MC whose lower page data is “1,” a program for raising the threshold level from Er level to EP level is executed.

When the lower page program for word line WL1 is completed, the NAND flash memory 1 goes into the ready state and the RP signal goes into the “H” level. Then, the controller instructs the NAND flash memory 1 to program upper page data for word line WL0. Specifically, as shown at point C in FIGS. 9 and 10, the controller inputs a program command, an address (corresponding to the upper page of WL0), and upper page data to the NAND flash memory 1. When a program command has been established at the command user interface 14 in response to this, the NAND flash memory 1 goes into the busy state.

When a program command has been established, an upper-page program for word line WL0 is executed under the control of the sequencer 13 (steps S27 to S29 in FIG. 8).

Hereinafter, similar processes are repeated. As described above, data is basically written sequentially, starting with word line WL0 closest to source line SL. Word line WL7 closest to bit line BL is written onto last. In addition, an upper page data program for word line WLn is executed after a lower page data program for word line WL(n+1) adjacent to word line WLn on the drain side has been executed.

1.2.4 Concrete Example of Write Operation

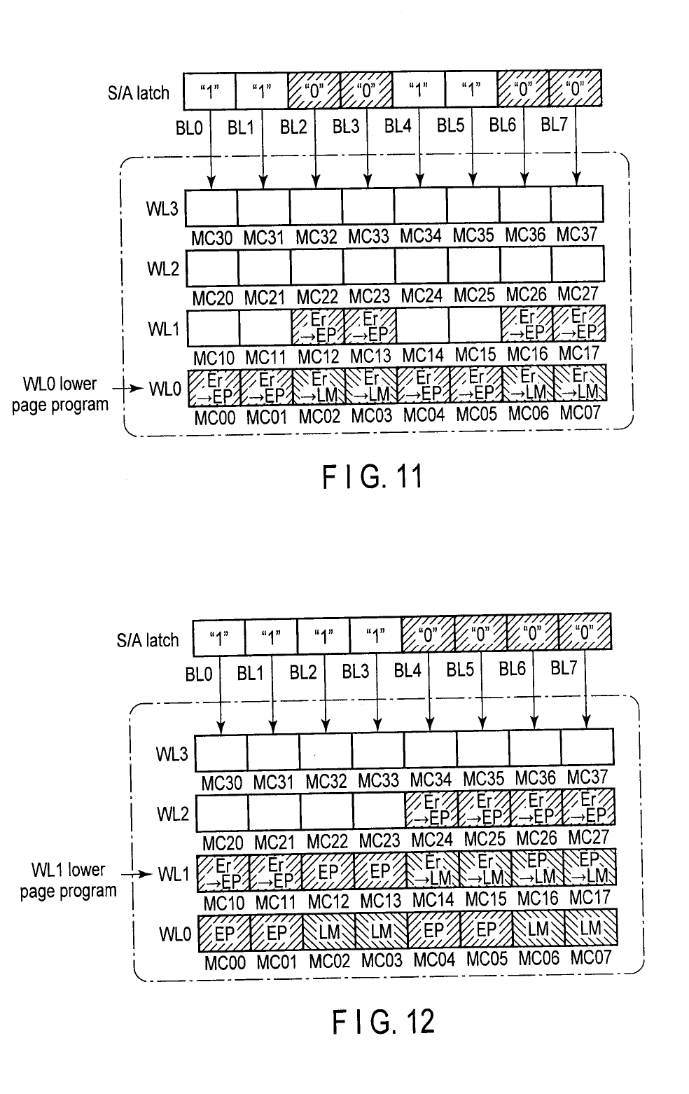

Next, a concrete example of the write operation explained above will be explained briefly with reference to FIGS. 11 to 14. FIGS. 11 to 14 are schematic views of the memory cell array 2 and a latch circuit provided for each bit line in the page buffer 4. For ease of explanation, FIGS. 11 to 14 show an example where four word lines WL and eight bit lines are used. In reference symbol MCij in FIGS. 11 to 14, indicates the corresponding word line (row) number and j indicates the corresponding bit line (column) number. Therefore, a memory cell connected to word line WL0 and bit line BL1 is represented as MC01. Of rectangular boxes representing memory cells, white ones represent memory cells at Er level.

First, as shown in FIG. 11, the NAND flash memory 1 receives “11001100” as lower page data for word line WL0 from the controller. Each bit in the received data is stored in the corresponding latch.

Then, first, programming for word line WL0 is not performed and an erase-program for word line WL1 adjacent to word line WL0 on the drain side is executed. Specifically, the threshold levels of memory cells MC12, MC13, MC16, and MC17 corresponding to bit lines BL2, BL3, BL6, and BL7 to which data “0” is transferred are raised from Er level to EP level. Thereafter, a lower-page program is executed for word line WL0. In the example of FIG. 11, the threshold levels of memory cells MC02, MC03, MC06, and MC07 corresponding to bit lines BL2, BL3, BL6, and BL7 to which data “0” is transferred are raised from Er level to LM level. On the other hand, the threshold levels of memory cells MC00, MC01, MC04, and MC05 corresponding to bit lines BL0, BL1, BL4, and BL5 to which data “1” is transferred are raised from Er level to EP level.

As shown in FIG. 12, the NAND flash memory 1 receives “11110000” as lower page data for word line WL1 from the controller. Each bit in the received data is stored in the corresponding latch.

Then, first, an erase-program for word line WL2 adjacent to word line WL1 on the drain side is executed. Specifically, the threshold levels of memory cells MC24, MC25, MC26, and MC27 corresponding to bit lines BL4 to BL7 to which data “0” is transferred are raised from Er level to EP level. Thereafter, a lower-page program is executed for word line WL1. In the example of FIG. 12, the threshold levels of memory cells MC14, MC15, MC16, and MC17 corresponding to bit lines BL4 to BL7 to which data “0” is transferred are raised from Er level or EP level to LM level. On the other hand, the threshold levels of memory cells MC10 and MC11 corresponding to bit lines BL0 and BL1 to which data “1” is transferred are raised from Er level to EP level. Memory cells MC12 and MC13 for which the erase-program was executed at the time of FIG. 11 are inhibited from being erased, with the result that the threshold levels are maintained at EP level.

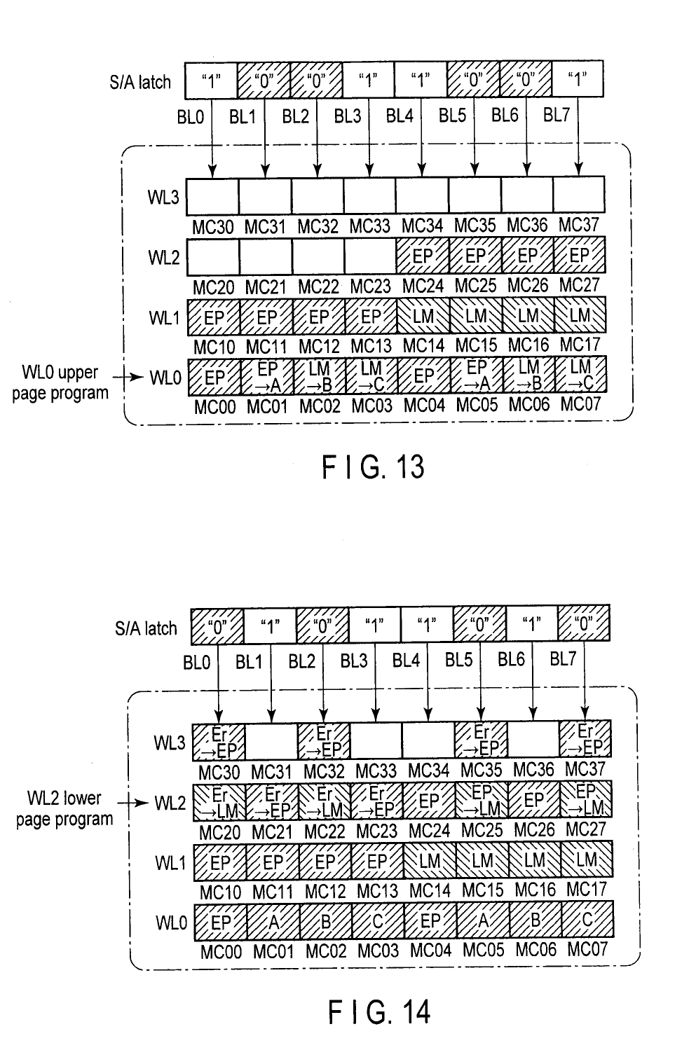

Next, as shown in FIG. 13, the NAND flash memory 1 receives “10011001” as upper page data for word line WL0 from the controller. Each bit in the received data is stored in the corresponding latch. Then, an upper-page program is executed for word line WL0. As a result, the threshold level of a memory cell MC connected to word line WL0 is any one of EP, A, B, and C levels.

Next, as shown in FIG. 14, the NAND flash memory 1 receives “01011010” as lower page data for word line WL2 from the controller. Each bit in the received data is stored in the corresponding latch.

Then, an erase-program is executed for word line WL3 adjacent to word line WL2 on the drain side. Specifically, the threshold levels of memory cells MC30, MC32, MC35, and MC37 corresponding to bit lines BL0, BL2, BL5, and BL7 to which data “0” is transferred are raised from Er level to EP level. Thereafter, a lower-page program is executed for word line WL2.

1.3 Effects of the First Embodiment

With the configuration of the first embodiment, the operating speed of the NAND flash memory can be improved. This effect will be explained in detail.

1.3.1 Characteristics of Three-Dimensional NAND Flash Memory

With the three-dimensional structure NAND flash memory explained with reference to FIGS. 1 to 4, the data retention characteristic of memory cells deteriorates more than a structure where memory cells are arranged two-dimensionally on a semiconductor substrate. The reason is that charge coupling is liable to take place between adjacent memory cells because the charge accumulation layer is continued in the same string. More specifically, since Er level may have a negative value, if each of the threshold levels of two adjacent memory cells sharing the charge accumulation layers are Er level and one of A to C levels, charge coupling occurs between a positive charge and a negative charge. As a result, the threshold levels of the memory cells might fluctuate.

1.3.2 Erase-Programming

To prevent the data retention characteristic from deteriorating, a method of making positive the threshold level of a memory cell in a data erased state (or a memory cell that holds data corresponding to the lowest threshold level) can be considered. This is an erase-program. However, when this method is simply used, an erase-program has to be executed each time data is erased, causing the problem of increasing data rewrite time.

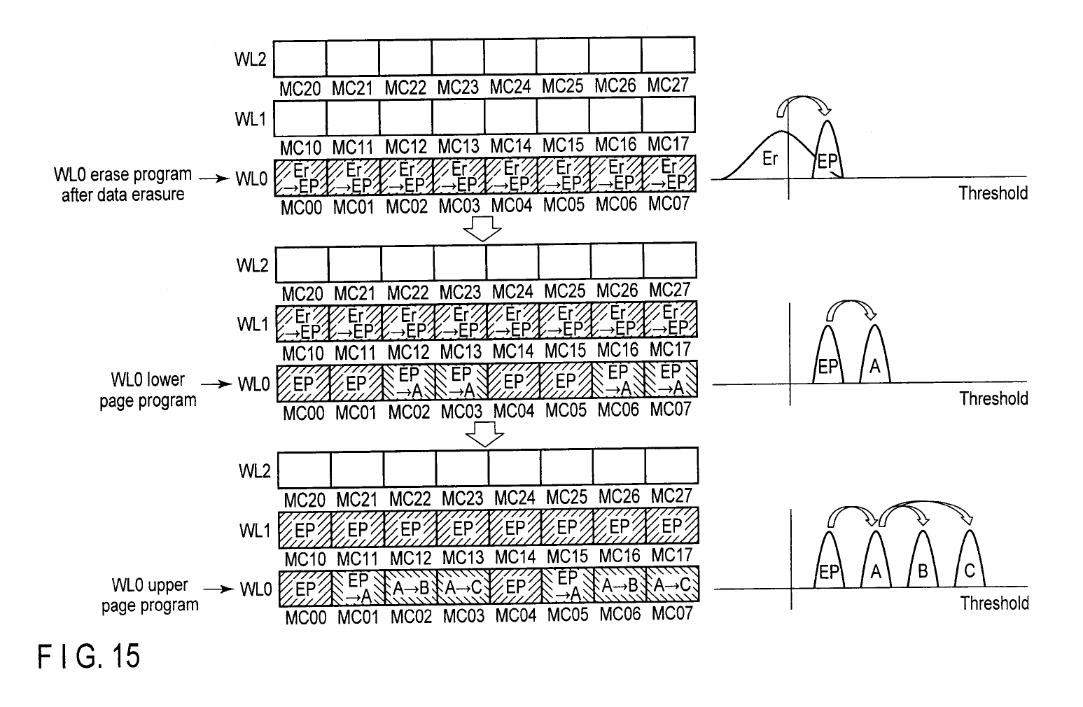

FIG. 15 is a schematic view to explain fluctuations in the threshold level of a memory cell during the time from immediately after erasing until upper-page data is written onto word line WL0 in a case where an erase-program is simply used.

As shown in FIG. 15, when data has been erased, an erase-program is executed for word line WL0 closest to the source line (or a page with the leading row address) in each NAND string. As a result, in a plurality of NAND strings that share select gate lines SGD, SGS, the threshold levels of all the memory cells MC00 to MC07 connected to word line WL0 are brought to EP level.

Next, an instruction to execute a lower-page program for word line WL0 is given. Then, before word line WL0 is written onto, an erase-program is executed for word line WL1 adjacent to word line WL0 on the drain side. This is also executed for all the memory cells MC10 to MC17 connected to word line WL1. Thereafter, lower-page data is written into memory cells MC00 to MC07 connected to word line WL0.

After that, an upper-page program for word line WL0 is executed.

As described above, with the method of FIG. 15, the erase-program is executed for all the memory cells MC connected to any one of the word lines WL that has been made a target. Therefore, when data is rewritten, the number of memory cells for which a program is executed becomes very large, which might result in a decrease in the operating speed.

1.3.3 First Embodiment

With the configuration of the first embodiment, an erase-program for a word line adjacent to the selected word line on the drain side is executed on the basis of lower-page data for the selected word line.

More specifically, for example, as shown in FIG. 11, an erase-program is executed for a column (BL2, BL3, BL6, and BL7 in the example of FIG. 11) in which data corresponding to a high threshold level (B level and C level in the example of FIG. 11) is to be written. On the other hand, an erase-program is not executed for a column (BL0, BL1, BL4, and BL5 in the example of FIG. 11) in which data corresponding to a low threshold level (EP level and A level in the example of FIG. 11) is to be written, causing the threshold levels of memory cells MC10, MC11, MC14, and MC15 to remain at Er level.

As described above, decreasing the number of memory cells for which the erase-program is executed enables the data rewriting speed to be increased. Of course, the time required to program a page is controlled by a memory cell with the worst characteristic. However, if the number of memory cells for which the program is executed decreases, the frequency of writing data into such a memory cell is decreased, enabling the operating speed to be increased.

In addition, even if an erase-program is not executed for all the memory cells, an adverse effect on the data retention characteristic can be minimized. This will be explained below.

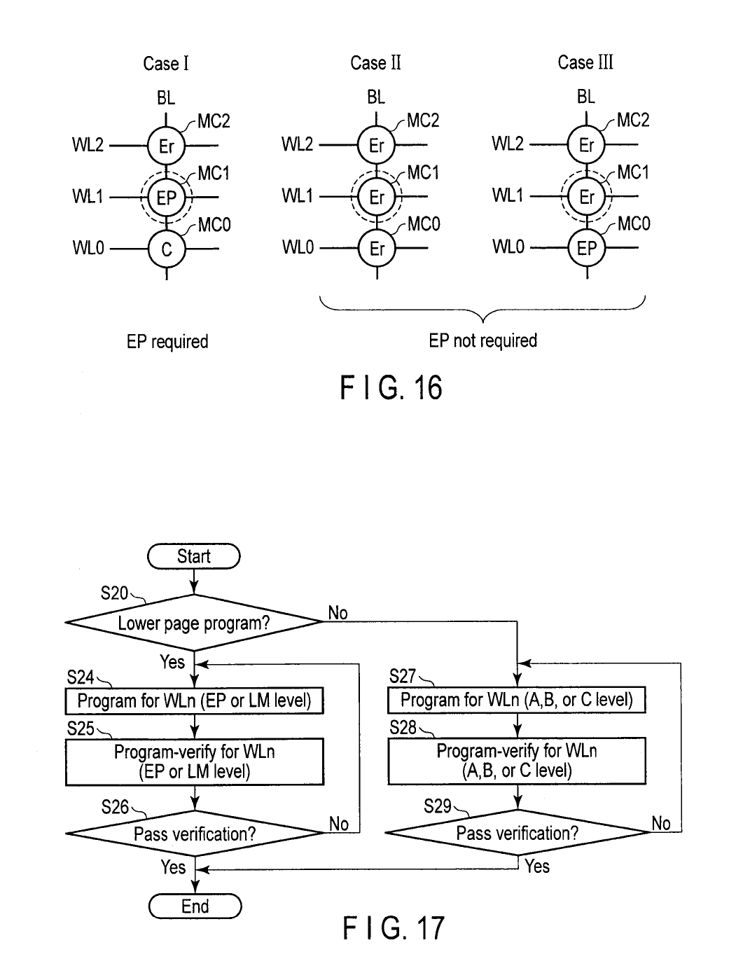

The deterioration of the data retention characteristic results from a large difference in threshold level between adjacent memory cells. A case shown in FIG. 16 can be considered in connection with the relationship between adjacent memory cells. In FIG. 16, word line WL1 is a word line for which an erase-program is executed.

In CASE I of FIG. 16, memory cell MC0 adjacent to memory cell MC1 of word line WL1 on the source line side is at C level in threshold level. In this case, if the threshold level of memory cell MC1 remains at Er level, the threshold level difference is too large and therefore an erase-program is needed to be executed for memory cell MC1.

In contrast, the threshold level of memory cell MC0 is at Er level in CASE II and at EP level in CASE III. Since the threshold level difference is not large in these, cases, even if the execution of an erase-program for memory cell MC1 is omitted, it is conceivable that the omission will not particularly have an adverse effect on the data retention characteristic.

As described above, in the first embodiment, if a memory cell adjacent to memory cell MC1 on the source side is at Er level or EP level, the erase-program is not executed. This enables the writing speed to be improved.

Furthermore, an erase-program for word line WL0 is executed when word line WL0 is written onto, not immediately after erasing. This enables the time required for an erase operation to be decreased.

When this writing method is used, all the memory cells MC to be written into are at Er level in threshold level even in a certain NAND string in writing lower-page data onto word line WL0 closest to the source side. Then, all the memory cells MC in the selected NAND string 16 connected to word line WL0 are programmed. The verification level in writing is set at EP level or LM level.

More specifically, the writing of a block for the first time is started with the lower page of word line

WL0 closest to the SGS. As its preprocessing, an erase-program for the next word line WL1 adjacent to word line WL0 is executed. At this time, unlike the example of FIG. 15, an erase-program is not necessarily executed for all the memory cells MC and is executed only for the memory cells of WL1 on the same bit line as that of the memory cells MC with lower-page data of WL0 being “0”.

After that, lower-page data of WL0 is programmed. At this time, too, unlike the example of FIG. 15, all the memory cells MC are to be programmed. Specifically, a memory cell MC with write data being “1” is written into with a write target threshold distribution at EP level. On the other hand, a memory cell MC with write data being “0” is written into with the write target threshold distribution at LM level.

Thereafter, upper-page data for WL0 is written. At this time, the erase-program for WL1 has been already executed.

With this method, the threshold level of a memory cell adjacent to a memory cell programmed so as to be at a high threshold level (B level or C level) is always at EP level and therefore higher than Er level. Therefore, a fluctuation in the threshold level due to charge coupling between a positive charge and a negative charge can be suppressed.

With the first embodiment, as compared with the method of FIG. 15, the time required to perform an operation can be decreased in the following two points. A first point is that an erase-program for an adjacent WL is not necessarily executed for all the memory cells. Depending on write data, the number of memory cells for which the erase program is executed can be decreased. Generally, as the number of memory cells written into is smaller, the memory cells are less liable to be affected by a variation in the write characteristic, which improves the writing speed.

A second point is that all the memory cells, including a memory cell whose threshold target is EP level, are programmed in writing a page at a write target address. Eventually, threshold levels of all the memory cells in data-written page are set to levels higher than Er level, and therefore a memory cell not set at EP level in writing an adjacent WL is set at EP level at this stage. Writing at this stage is performed at the same time a memory cell whose LM level is a target threshold is written into. Since LM level is higher than EP level, writing at LM level generally takes a longer time than writing at EP level. Therefore, writing at EP level has no effect on the writing speed at this stage.

Furthermore, with the first embodiment, an erase-program for WL0 is executed in writing onto WL0. Therefore, unlike FIG. 15, an erase-program in an erasing operation is not needed. Accordingly, the time required for an erasing operation can be decreased.

### 2. Second Embodiment

Next, a semiconductor memory device according to a second embodiment will be explained. The second embodiment is such that an erase-program for an adjacent word line is omitted in the first embodiment. Hereinafter, only what differs from the first embodiment will be explained.

2.1 Write Operation

FIG. 17 is a flowchart to explain processing flow in writing data according to the second embodiment.

As shown in FIG. 17, a writing method according to the second embodiment is such that the processes in step S21 to S23 are omitted in the method explained with reference to FIG. 8 in the first embodiment. Therefore, when lower-page data is programmed for each word line WL, the threshold levels of all the memory cells MC connected to the word line WL are at Er level. Then, Er level is raised to EP level or LM level.

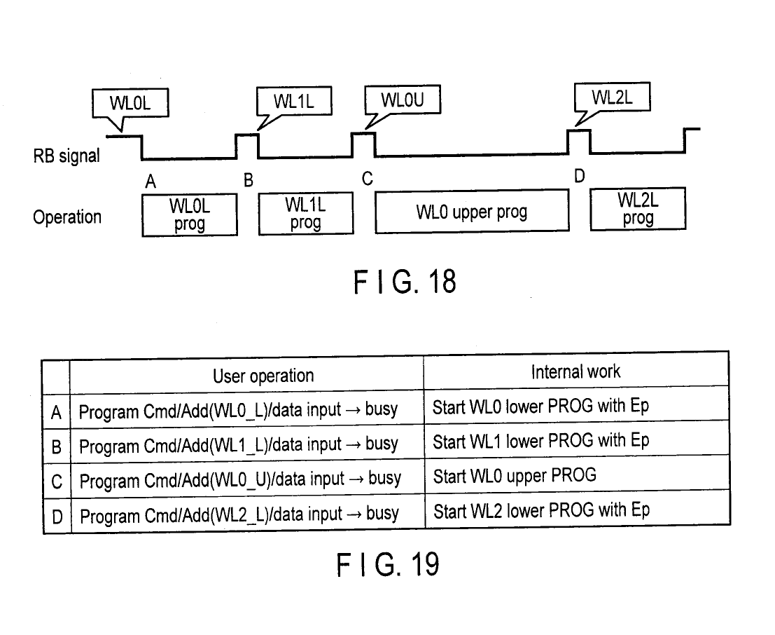

FIGS. 18 and 19 show the details of the sequence in a write operation according to the second embodiment. FIG. 18 is a timing chart to explain a ready/busy signal (RB signal) supplied from the NAND flash memory 1 to the controller and an operation flow. FIG. 19 is a table to explain the details of the operation of FIG. 18.

As shown in FIGS. 18 and 19, the write sequence according to the second embodiment is such that the internal works (erase-programs for adjacent word lines) at points A, B, and D are omitted in the sequence explained with reference to FIGS. 9 and 10 in the first embodiment.

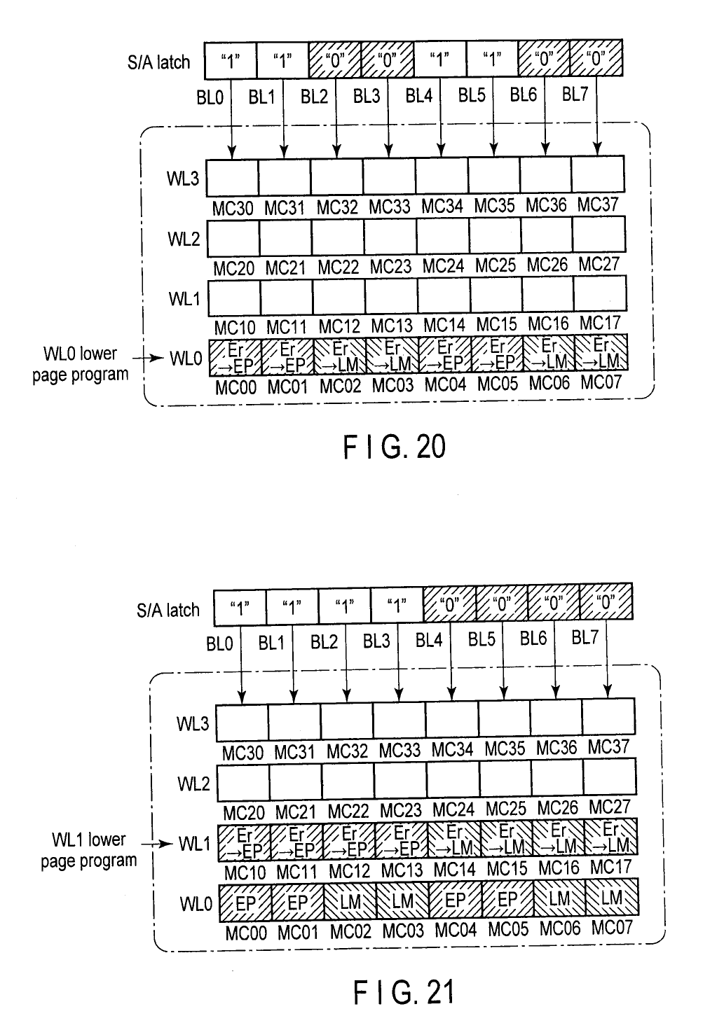

A concrete example of write operation according to the second embodiment will be explained with reference to FIG. 20 to FIG. 23. FIG. 20 to FIG. 23 are schematic views of a memory cell array 2 and latch circuits provided for respective bit lines in a page buffer 4. FIG. 20 to FIG. 23 correspond to FIG. 11 to FIG. 14 explained in the first embodiment.

First, as shown in FIG. 20, the NAND flash memory 1 receives “11001100” as lower page data for word line WL0 from the controller. Each bit in the received data is stored in the corresponding latch.

Then, lower-page data is written onto word line WL0 without executing an erase-program on word line WL1. As a result, the threshold levels of the memory cells MC connected to word line WL0 are raised from Er level to EP level or LM level. The threshold levels of the memory cells MC connected to word line WL1 remain at Er level.

Next, as shown in FIG. 21, the NAND flash memory 1 receives “11110000” as lower page data for word line WL1 from the controller. Each bit in the received data is stored in the corresponding latch.

Then, lower-page data is written onto word line WL1 without executing an erase-program on word line WL2. As a result, the threshold levels of the memory cells MC connected to word line WL1 are raised from Er level to EP level or LM level. The threshold levels of the memory cells MC connected to word line WL2 remain at Er level.

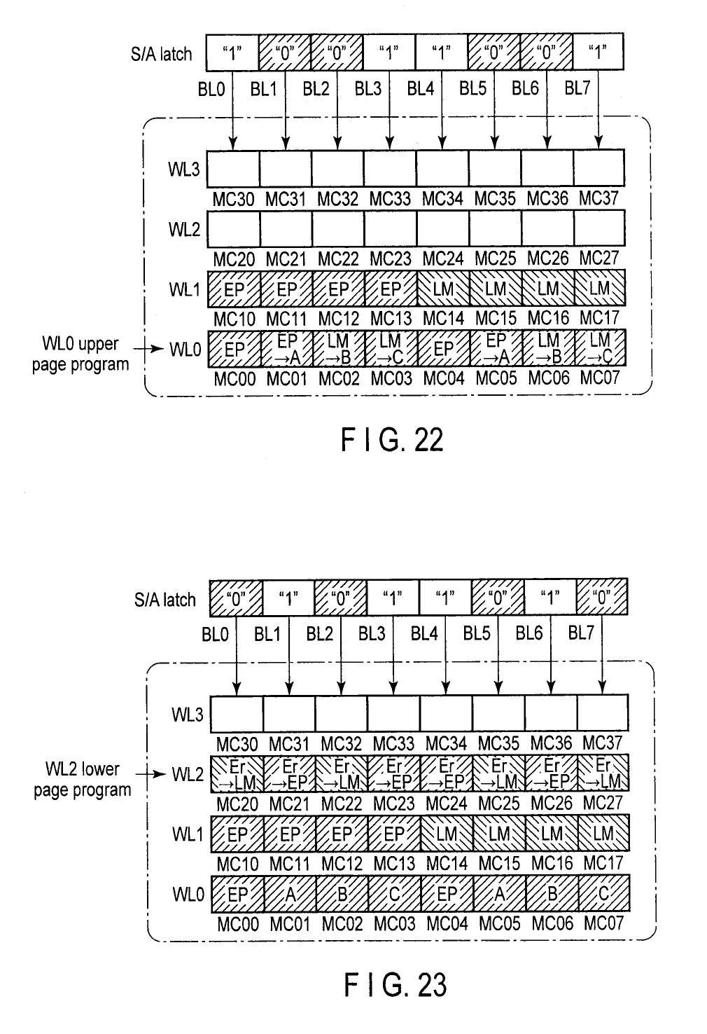

Next, as shown in FIG. 22, in the NAND flash memory 1, upper-page data is written onto word line WL0.

Next, as shown in FIG. 23, the NAND flash memory 1 receives “01011010” as lower page data for word line WL2 from the controller. Then, lower-page data is written onto word line WL2 without executing an erase-program on word line WL3.

Since a method of erasing data is the same as that of FIG. 7 explained in the first embodiment, an explanation will be omitted.

2.2 Effects of the Second Embodiment

With the second embodiment, when a lower-page programming is performed, an erase-programming for adjacent word lines is omitted. Therefore, data rewriting speed can be improved more than in the first embodiment.

Because of the characteristic of the reliability of a memory cell, if the threshold level of a memory cell adjacent to a memory cell at Er level is at LM level, the probability of charge coupling might be low. In such a case, it is conceivable that the data retention characteristic does not deteriorate much even if an erase-program is not executed on a memory cell at Er level. Therefore, omitting an erase-program as in the method of the second embodiment enables the operating speed to increase further.

### 3. Modifications

As described above, the semiconductor memory device 1 according to the second embodiment includes a plurality of memory cells MC each of which is capable of holding two or more bits of data according to a threshold level; and a plurality of memory strings 16 each of which includes a plurality of memory cells connected in series. Data is written in units of page PG into memory cells MC and the page PG includes a lower page and upper page which are associated with lower bits and upper bits of the two or more bits of data, respectively. When lower-page data is first written into a memory string 16, all memory cells (MC00 to MC07 in FIG. 11) corresponding to the lower-page data are made write-target, a program-verifying level of first ones (MC00, MC01, MC04, and MC05 shown in FIG. 11) of the write-targeted memory cells is a first threshold level (EP-level), and a program-verifying level of second ones (MC02, MC03, MC06, and MC07 shown in FIG. 11) of the write-targeted memory cells is a second threshold level (LM-level). The first threshold level (EP-level) corresponds to data (“11” in FIG. 5) associated with the lowest threshold level of the two or more bits of data and is higher than a third threshold level (Er-level). The third level is a threshold level at which data has been erased. The second threshold level (LM-level) is higher than the first threshold level (EP-level).

With this configuration, the memory cells are erase-programmed efficiently, enabling the time required to execute the erase program to be decreased. As a result, the time required to rewrite the entire data can be decreased. In addition, when the threshold level of an adjacent memory cell is at LM level to assure the reliability of memory cells, the omission of the erase-program enables the writing time to be decreased further.

The embodiments explained above may be modified variously. For example, in the embodiments, each of the memory cells MC hold 2-bit data. However, each memory cell may hold three or more bits of data.

In addition, in the embodiments, an erase-program has been executed on an adjacent word line when write data corresponds to B level and C level. However, whether the erase-program is to be executed may be determined as needed. For example, in the embodiments, even when A level is to be written, the erase-program may be executed. Alternatively, when B level is to be written, the erase-program may not be executed. The same holds true for three or more bits of data.

Furthermore, in the embodiments, the explanation has been given, taking a three-dimensional stacked NAND flash memory as an example. The embodiments may be applied to a normal planar NAND flash memory where memory cells have been arranged two-dimensionally on a semiconductor substrate or to a storage device other than the NAND flash memory.

Moreover, the methods explained in the embodiments enable the sequence to be changed as much as possible. A concrete structure of the NAND flash memory 1 is not limited to the configuration explained in FIG. 1 to FIG. 4. In addition, the threshold distribution shown in FIG. 5 is illustrative only. The relationship between “00” to “11” data and the threshold distribution is arbitrary.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of memory cells each of which is capable of holding two or more bits of data according to a threshold level; and
a plurality of memory strings each of which includes a plurality of memory cells connected in series,
wherein data is written in units of page into memory cells and the page includes a lower page and upper page which are associated with lower bits and upper bits of the two or more bits of data, respectively,
when lower-page data is first written into a memory string, all memory cells corresponding to the lower-page data are made write-target, a program-verifying level of first ones of the write-targeted memory cells is a first threshold level, and a program-verifying level of second ones of the write-targeted memory cells is a second threshold level,
the first threshold level corresponds to data associated with the lowest threshold level of the two or more bits of data and is higher than a third threshold level,
the third level is a threshold level at which data has been erased, and
the second threshold level is higher than the first threshold level.

2. The device of claim 1, wherein, when an instruction to write lower-page data on a first page is received, an erase-programming is executed on a word line corresponding to a second page adjacent to the first page before the lower-page data is written, thereby raising the threshold level of one of the memory cells connected to the word line from the third threshold level to the first threshold level.

3. The device of claim 2, wherein the erase programming is executed based on the lower-page data on the first page.

4. The device of claim 3, wherein a first memory cell is erase-programmed, and a second memory cell is not erase-programmed, and
the first memory cell is in a column where the lower-page data on the first page corresponds to the second threshold level, the second memory cell is in a column corresponding to the first threshold level.

5. The device of claim 2, wherein the memory string further includes a first select transistor connected to a bit line and a second select transistor connected to a source line,
the memory cells are connected in series between the source of the first select transistor and the drain of the second select transistor,
the first page is associated with a first word line,
the second page is associated with a second word line, and
the first word line is located closer to a source line than the second word line is.

6. The device of claim 1, wherein the lower-page data is written in a state where the memory cells on all the pages in the memory string are at the third threshold level, and
writing the lower-page data causes the threshold levels of the memory cells to be raised from the third threshold level to the first or second threshold level.

7. The device of claim 1, wherein first writing of lower-page data into the memory string is performed on a memory cell connected to a word line closest to a source line in the memory string.

8. The device of claim 2, wherein writing of upper-page data on the first page is performed after the writing of lower-page data on the second page.

9. The device of claim 1, wherein the second threshold level is positive.

10. The device of claim 1, wherein the memory cells are stacked on a semiconductor substrate.

11. A method of writing data into a semiconductor memory device, comprising:
erasing, en bloc, data in a plurality of first memory cells and a plurality of second memory cells to set threshold levels of the first and second memory cells at a first level, each of the first memory cells and the second memory cells being capable of holding two or more bits of data according to a threshold level, the first memory cells being connected equally to a first word line, and the second memory cells being connected equally to a second word line adjacent to the first word line; and
writing lower-page data of a first page into the first memory cells to raise a threshold level of one of the first memory cells from the first level to a second level and a threshold level of another one of the first memory cells from the first level to a third level higher than the second level,
wherein the second level corresponds to first data at the lowest one of the threshold levels of the two or more bits of data.

12. The method of claim 11, further comprising:
receiving the lower-page data of the first page and a write instruction after the erasing data; and
erase-programming on at least a part of the second memory cells based on the lower-page data of the first page to raise the threshold levels of the part from the first level to the second level,
wherein the lower-page data of the first page is written to the first memory cells after the erase-programming.

13. The method of claim 12, wherein a first one of the second memory cells is erase-programmed, and a second one of the second memory cells is not erase-programmed, and
the first one of the second memory cells is in the same column as that of the first memory cells whose threshold level is raised to the third level, and
the second one of the second memory cells is in the same column as that of the first memory cells whose threshold level is raised to the second level.

14. The method of claim 11, wherein the writing lower-page data is executed in a state where the threshold levels of the memory cells on all the pages are at the first level, and
the writing lower-page data causes the threshold levels of the memory cells to be raised from the first level to the second or third level.

15. The method of claim 11, wherein the first word line is a word line closest to a source line.

16. The method of claim 11, wherein the second threshold level is positive.

17. The method of claim 11, wherein the memory cells are stacked above a semiconductor substrate.
